(19) United States
(12) Patent Application Publication
(10) Pub. No.: US 2025/0391787 A1
(43) Pub. Date: Dec. 25, 2025

(54) ELECTRONIC DEVICE PACKAGE

(71) Applicant: Advanced Semiconductor Engineering, Inc., Kaohsiung (TW)

(72) Inventor: Kuo Feng HUANG, Kaohsiung (TW)

(21) Appl. No.: 18/752,387

(22) Filed: Jun. 24, 2024

(51) Int. Cl. H01L 23/58; H01L 23/00; H01L 23/36; H01L 23/48; H01L 23/49; H01L 23/538; H01L 25/16

(52) U.S. Cl. CPC H01L 23/58; H01L 23/481; H01L 23/49; H01L 23/5385; H01L 24/16; H01L 25/162; H01L 23/36; H01L 2224/16225

(57) ABSTRACT

The present disclosure relates to an electronic device package that includes a first substrate, a second substrate over the first substrate, and an integrated circuit (IC) connected between the first substrate and the second substrate. The IC is configured to regulate a power signal, wherein a projection of a power signal path between the IC and the second substrate on the first substrate is entirely within a projection of the IC on the first substrate.

### BACKGROUND

### 1. Technical Field

The present disclosure generally relates to an electronic device package, and more particularly to an electronic device package including a power regulating component having double-sided terminals.

### 2. Description of the Related Art

The present electronic device package includes a power management integrated circuit (PMIC), which performs various functions related to power supply such as battery management, voltage regulation, and charging. The PMIC receives a power signal and delivers the regulated power signal to other components of the electronic device package. Due to increasing power consumption of components such as chips, a longer electrical path may lead to further increases in power consumption. In addition, the required lateral power signal path on the substrate increases circuit footprint on the substrate of the electronic device package. Improvements in electronic device packaging are correspondingly called for.

### SUMMARY

In some embodiments, an electronic device package includes a first substrate, a second substrate over the first substrate, and an integrated circuit (IC) connected between the first substrate and the second substrate. The IC is configured to regulate a power signal, wherein a projection of a power signal path between the IC and the second substrate on the first substrate is entirely within a projection of the IC on the first substrate.

In some embodiments, an electronic device package includes a first substrate, a first electronic component disposed on the first substrate, and an IC supporting the first substrate and configured to regulate a power signal to the first electronic component.

In some embodiments, an electronic device package includes a first substrate, a second substrate over the first substrate, and an IC disposed between the first substrate and the second substrate. A power path is composed of a first path through the first substrate, a second path through the IC, and a third path through the second substrate, wherein the second path is perpendicular to the first path and the third path.

### BRIEF DESCRIPTION OF THE DRAWINGS

Aspects of the present disclosure are readily understood from the following detailed description when read with the accompanying figures. It should be noted that various features may not be drawn to scale. The dimensions of the various features may be arbitrarily increased or reduced for clarity of discussion.

FIG. 1 is a cross-section of an electronic device package, in accordance with some embodiments of the present disclosure.

FIG. 2 is a cross-section of an electronic component, in accordance with some embodiments of the present disclosure.

FIG. 3A is a cross-section of an inductor, in accordance with some embodiments of the present disclosure.

FIG. 3B is a top view of an inductor, in accordance with some embodiments of the present disclosure.

FIG. 4A is a cross-section of an inductor, in accordance with some embodiments of the present disclosure.

FIG. 4B is a top view of an inductor, in accordance with some embodiments of the present disclosure.

FIG. 5 is a cross-section of an electronic device package, in accordance with some embodiments of the present disclosure.

FIG. 6 is a cross-section of an electronic component, in accordance with some embodiments of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

The following disclosure provides different embodiments, or examples, for implementing different features of the provided subject matter. Specific examples of components and embodiments are recited herein. These are, of course, merely examples and are not intended to be limiting. In the present disclosure, reference to the formation of a first feature over or on a second feature in the description that follows may include embodiments in which the first and second features are formed in direct contact, and may also include embodiments in which additional features may be formed between the first and second features, such that the first and second features may not be in direct contact. The present disclosure may repeat reference numerals and/or letters in the various examples. This repetition is for simplicity and clarity and does not in itself dictate a relationship between the various embodiments and/or configurations discussed.

Embodiments of the present disclosure are discussed in detail as follows. It should be appreciated, however, that the present disclosure provides many applicable concepts that can be embodied in a wide variety of specific contexts. The specific embodiments discussed are merely illustrative and do not limit the scope of the disclosure.

Problems from increased power consumption and limited size can be addressed by a PMIC having double-sided terminals and integrating passive elements. A vertical electrical connection provided by the PMIC provides a shorter electrical path, reducing area required in the substrate. In addition, passive elements such as inductors, capacitors, and resistors integrated into the PMIC can even decrease the area demanded on the substrate and increase performance (for example, power stability) of the PMIC.

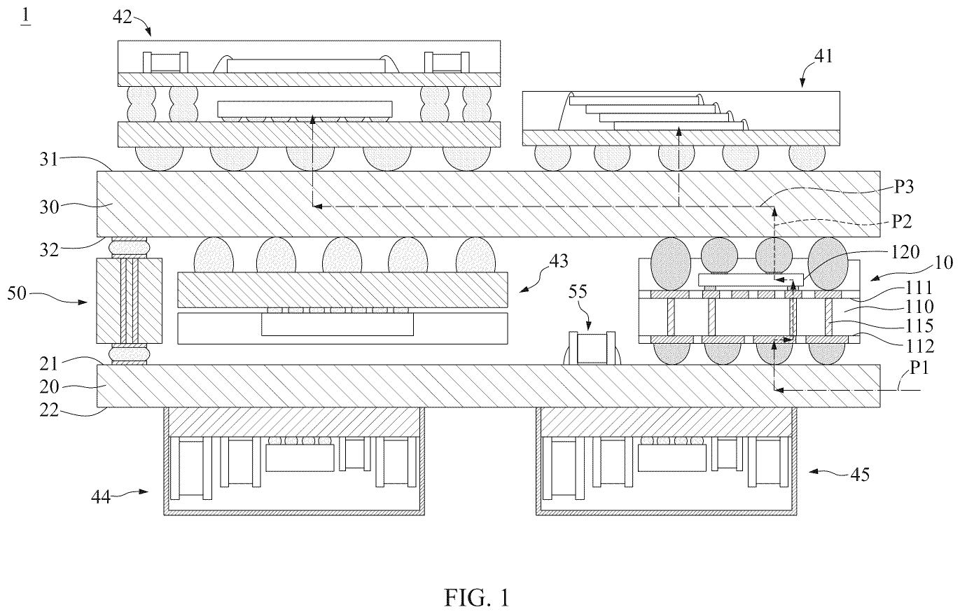

FIG. 1 is a cross-section of an electronic device package 1, in accordance with some embodiments of the present disclosure. In some embodiments, the electronic device package 1 may include one or more electronic devices or semiconductor devices. In some embodiments, the electronic device package 1 may be a semiconductor device package structure.

Referring to FIG. 1, the electronic device package 1 may include two substrates 20 and 30, one or more electronic components 10, 41, 42, 43, 44, and 45, at least one interconnector 50, and at least one passive element 55. The electronic component 10 may include, but is not limited to, a power regulating component. For example, the electronic component 10 may include a power management integrated circuit (PMIC).

In some embodiments, the substrate 30 may be disposed over the substrate 20. The substrate 20 may have a top surface 21 and a bottom surface 22 opposite to the top surface 21. The substrate 30 may have a top surface 31 and a bottom surface 32 opposite to the top surface 31. In some embodiments, the substrates 20 and 30 may overlap vertically. That is, the bottom surface 32 of the substrate may face the top surface 21 of the substrate 20. Therefore, the electronic device package 1 may have a vertical stacked structure.

In some embodiments, the substrates 20 and 30 may be configured to support one or more electronic components. For example, the substrate 20 may support electronic components 41, 42, and 43. The substrate 30 may support the electronic components 10, 44, and 45.

In some embodiments, the substrates 20 and 30 may be multilayered. In some embodiments, the substrates 20 and 30 may include at least one dielectric layer and a redistribution structure, traces, and/or circuit, for electrical connection among components, embedded in the dielectric layer. In some embodiments, the substrates 20 and 30 may include a circuit board, such as a paper-based copper foil laminate, a composite copper foil laminate, or a polymer-impregnated glass-fiber-based copper foil laminate. In some embodiments, the substrates 20 and 30 may include a semiconductor substrate. For example, the substrates 20 and 30 may include silicon, germanium, or other suitable materials. The substrates 20 and 30 may be the same or different types.

In some embodiments, the substrates 20 and 30 may be stacked to free space for accommodating one or more elements, such as the electronic component 10, electronic component 43, and passive element 55. In some embodiments, the substrates 20 and 30 may have a substantially identical width. In some embodiments, the substrates 20 and 30 may have the same or different thicknesses. For example, the thickness of the substrate 30 may be greater than the thickness of the substrate 20.

The electronic components 41 and 42 may be disposed on the substrate 30. In some embodiments, the electronic components 41 and 42 may be disposed on the top surface 31 of the substrate 30. The electronic component 41 may be disposed beside the electronic component 42. The electronic component 41 may be electrically connected to the electronic component 42 through the substrate 30. In some embodiments, the electronic components 41 and 42 may be a sub-package structure, which may include a substrate and one or more dies disposed on the substrate.

In some embodiments, the electronic components 41 and 42 may include a chip, a die, a circuit, or a circuit element that relies on an external power supply to control or modify electrical signals. For example, the electronic components 41 and 42 may include a processor, a controller, a memory, or an input/output (I/O) buffer, etc. In some embodiments, the electronic components 41 and 42 may include, for example, a central processing unit (CPU), a microprocessor unit (MPU), a graphics processing unit (GPU), a microcontroller unit (MCU), an application-specific integrated circuit (ASIC), a field-programmable gate array (FPGA), a flash memory, a random-access memory (RAM), a read-only memory (ROM), a transmitter, a receiver, a wireless transceiver, a wireless communication unit, a radio-frequency (RF) module, or another type of integrated circuit. In some embodiments, the electronic components 41 and 42 may be the same or different. For example, the electronic component 41 may be a MCU integrated with a flash memory, and the electronic component 42 may be a DDR memory device.

In some embodiments, the electronic component 43 may be disposed on the substrate 30. The electronic component 43 may be disposed between the substrates 20 and 30. The electronic component 43 may be disposed on the bottom surface 32 of the substrate 30. In some embodiments, the electronic component 43 may be disposed adjacent to the electronic component 10.

In some embodiments, the electronic component 43 may include a chip, a die, a circuit, or a circuit element that relies on an external power supply to control or modify electrical signals. For example, the electronic component 43 may include a processor, a controller, a memory, or an input/output (I/O) buffer, etc. In some embodiments, the electronic component 43 may include, for example, a central processing unit (CPU), a microprocessor unit (MPU), a graphics processing unit (GPU), a microcontroller unit (MCU), an application-specific integrated circuit (ASIC), a field-programmable gate array (FPGA), a flash memory, a random-access memory (RAM), a read-only memory (ROM), a transmitter, a receiver, a wireless transceiver, a wireless communication unit, a radio-frequency (RF) module, or another type of integrated circuit. For example, the electronic component 41 may be a processor.

In some embodiments, the electronic components 44 and 45 may be disposed on the substrate 20. The electronic components 44 and 45 may be disposed on the bottom surface 22 of the substrate 20. The electronic component 44 may be disposed beside the electronic component 45. The electronic component 44 may be electrically connected to the electronic component 45 through the substrate 20. In some embodiments, the electronic components 44 and 45 may be electrically connected to the electronic components 41, 42, and 43. In some embodiments, the electronic components 44 and 45 may be a sub-package structure, which may include a substrate and one or more dies disposed on the substrate.

In some embodiments, the electronic components 44 and 45 may include a chip, a die, a circuit, or a circuit element that relies on an external power supply to control or modify electrical signals. For example, the electronic components 44 and 45 may include a processor, a controller, a memory, or an input/output (I/O) buffer, etc. In some embodiments, the electronic components 44 and 45 may include, for example, a central processing unit (CPU), a microprocessor unit (MPU), a graphics processing unit (GPU), a microcontroller unit (MCU), an application-specific integrated circuit (ASIC), a field-programmable gate array (FPGA), a flash memory, a random-access memory (RAM), a read-only memory (ROM), a transmitter, a receiver, a wireless transceiver, a wireless communication unit, a radio-frequency (RF) module, or another type of integrated circuit. In some embodiments, the electronic components 44 and 45 may be the same or different. For example, the electronic component 44 may be a RF module, and the electronic component 45 may be a wireless communication unit.

In some embodiments, the interconnector 50 may be disposed between the substrates 20 and 30. The interconnector 50 may be connected to the bottom surface 32 of the substrate 30 and the top surface 21 of the substrate 20. In some embodiments, the interconnector 50 may be configured to provide signal communication. For example, the interconnector 50 may electrically connect the electronic components 41, 42, and 43 mounted on the substrate 30 to the electronic components 44 and 45 mounted on the substrate 20. In some embodiments, the interconnector 50 may include an interconnection structure, an interposer, or a substrate interposer.

In some embodiments, the passive element 55 may be disposed between the substrates 20 and 30. The passive element 55 may be disposed on the top surface 21 of the substrate 20. In other embodiments, more than one passive element 55 may be present. The passive element 55 may be a capacitor, an inductor, a resistor, or a combination thereof. In some embodiments, the passive element 55 may be configured to regulate the voltage and filter the signals.

In some embodiments, the electronic component 10 may be disposed between the substrates 20 and 30. The electronic component 10 may be disposed on the top surface 21 of the substrate 20. The electronic component 10 may be disposed on the bottom surface 32 of the substrate 30. In some embodiments, the electronic component 10 may be configured to support the substrate 30. In some embodiments, the electronic component 10 may be configured to provide a vertical electrical path (vertical power signal path) between the substrates 20 and 30.

In some embodiments, the electronic component 10 may include a chip, a die, a circuit, or a circuit element that relies on an external power supply to control or modify electrical signals. For example, the electronic component 10 may include a processor, a controller, a memory, or an input/output (I/O) buffer, etc. In some embodiments, the electronic component 10 may include, for example, a central processing unit (CPU), a microprocessor unit (MPU), a graphics processing unit (GPU), a microcontroller unit (MCU), an application-specific integrated circuit (ASIC), a field-programmable gate array (FPGA), or other type of integrated circuit. For example, the electronic component 10 may include a power management integrated circuit (PMIC).

In some embodiments, the electronic component 10 may be configured to regulate a power signal. The electronic component 10 may receive the power signal from the substrate 20 and then transmit the regulated power signal to the substrate 30. In some embodiments, the electronic component 10 may be configured to provide the regulated power signal to the electronic components 41 and 42 on the substrate 30.

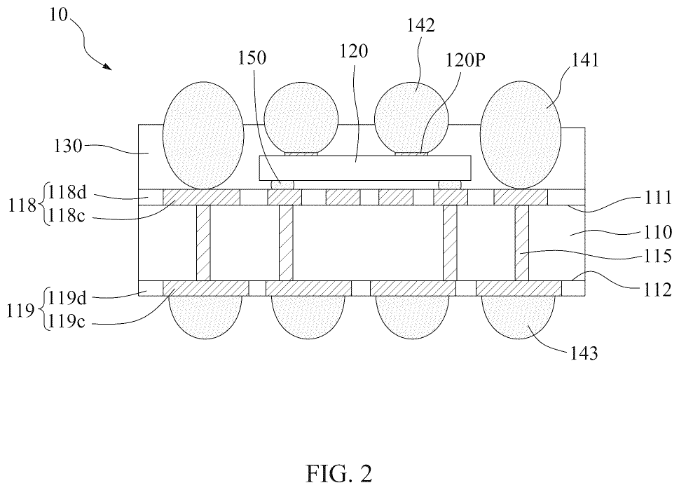

FIG. 2 is a cross-section of an electronic component 10, in accordance with some embodiments of the present disclosure. The electronic component 10 may include an integrated circuit (IC) 110, redistribution layers (RDL) 118 and 119, a passive element 120, an encapsulant 130, electrical contacts 141, 142, 143, and connectors 150.

Referring to FIG. 2, the IC 110 may have a top surface 111 and a bottom surface 112 opposite to the top surface 111. In some embodiments, the bottom surface 112 may be an active surface of the IC 110. The top surface 111 may be a backside surface of the IC 110. The bottom surface 112 may face the substrate 20 (see FIG. 1). In some embodiments, the IC 110 may be a power regulating component. The IC 110 may be a PMIC. The IC 110 may be configured to provide one or more types of power control to one or more electronic components of the electronic package 1 of FIG. 1.

In some embodiments, the IC 110 may include one or more conductive through vias 115 connecting two opposite surfaces (i.e., the bottom surface 112 and the top surface 111) of the IC. The conductive through vias 115 may penetrate the IC 110 and be exposed from the top surface 111 and the bottom surface 112. In some embodiments, the conductive through vias 115 may configured to transmit the power signals. For example, the IC 110 may receive the power signal from the substrate 20 through the bottom surface 112 and transmit the regulated power signal through the top surface 111 through the conductive through vias 115.

In some embodiments, the IC 110 may include a voltage regulator, such as a linear regulator (configured to maintain a constant output voltage) or a switching regulator (configured to generate an output voltage higher than or lower than the input voltage). In some embodiments, the IC 110 may include a step-down (buck) converter, a step-up (boost) converter, an analog-to-digital converter, a digital-to-analog converter, an AC-DC converter, a DC-DC converter, other types of converters, or a combination thereof.

The RDL 118 may be disposed on the top surface 111 of the IC 110. In some embodiments, the IC 110 may be configured to transmit the power signal through the RDL 118. The RDL 119 may be disposed on the bottom surface 112 of the IC 110. The IC 110 may be an IC layer sandwiched between the RDLs 118 and 119. In some embodiments, the conductive through vias 115 may be connected to the RDLs 118 and 119.

In some embodiments, the RDL 118 may include at least one dielectric layer 118d and a conductive trace 118c embedded in the dielectric layer 118d. The RDL 119 may include at least one dielectric layer 119d and a conductive trace 119c embedded in the dielectric layer 119d. In some embodiments, the RDLs 118 and 119 may each provide a fan-out horizontal electrical path for the IC 110. The RDL 118 may separate the IC 110 from the passive element 120.

In some embodiments, the passive element 120 may be disposed on the IC 110. The passive element 120 may be disposed on the top surface 111 of the IC 110. That is, the IC 110 and the passive element 120 overlap vertically. Referring back to FIG. 1, the passive element 120 may be electrically connected between the IC 110 and the substrate 30. The passive element 120 may be a capacitor, an inductor, a resistor, or a combination thereof. For example, the passive elements 120 may be a combination of a capacitor and an inductor. In some embodiments, the passive element 120 may be configured to regulate and filter power signals. In some embodiments, the passive element 120 can be configured to filter the power signals regulated by the IC 110 and then transmit the same to the substrate 30.

In some embodiments, the passive element 120 may be connected to the IC 110 through the connectors 150. For example, the connectors 150 can include conductive materials, such as solder balls. The connectors 150 may be electrically connected to the IC 110 through the RDL 118. In some embodiments, the connectors 150 may be connected to the conductive traces 118c.

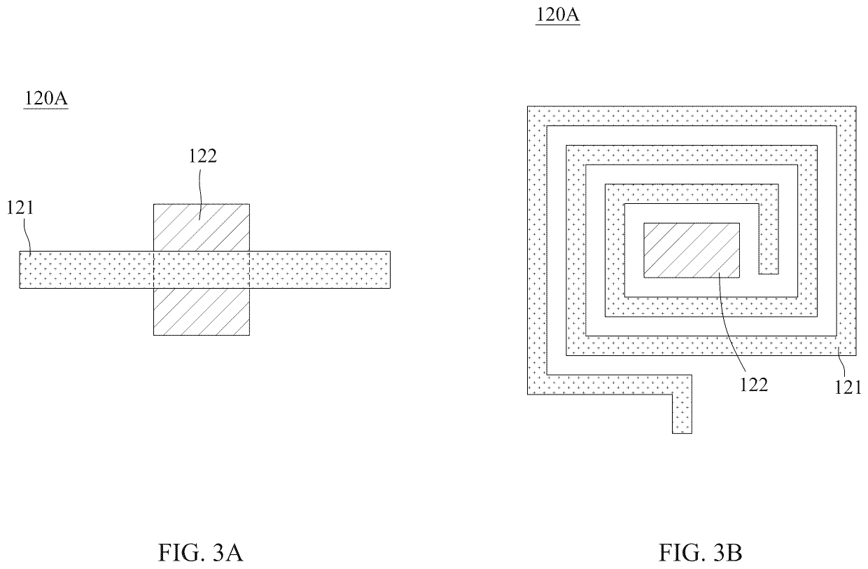

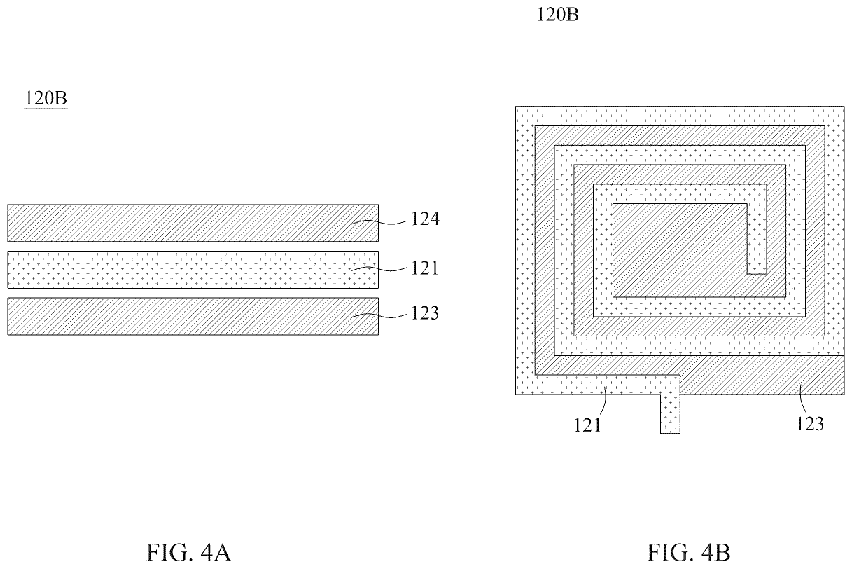

In some embodiments, the passive element 120 may include an inductor. In some embodiments, the passive element 120 may be a thin-film inductor. For example, the passive element 120 may include a conductive layer forming a coil. In some embodiments, the passive element 120 may include a magnetic inductor. Details of the magnetic inductor are shown in FIGS. 3A-3B and 4A-4B.

The electrical contacts 141 may be disposed on the top surface 111 of the IC 110. The electrical contacts 141 may be electrically connected to the IC 110 through the RDL 118. In some embodiments, the IC 110 may be electrically connected to the substrate 30 through the electrical contacts 141. In some embodiments, the electrical contacts (terminals) 141 may be directly contacted to the substrate 30. The electrical contacts 141 may overlap the passive element 120 horizontally. In some embodiments, the electrical contacts 141 may also be referred to as a terminal, a connecting element, an electrical connector, or the like. In some embodiments, the electrical contacts 141 may include a solder ball, such as a controlled collapse chip connection (C4) bump, a ball grid array (BGA) or a land grid array (LGA).

The electrical contacts 142 may be disposed on the passive element 120. The electrical contacts 142 may be electrical connected to the passive element 120 through conductive pads 120p. The electrical contacts 142 may be disposed between the passive element 120 and the substrate 30. In some embodiments, the electrical contacts (terminals) 142 may be directly contacted to the substrate 30. In some embodiments, the electrical contacts 142 may be substantially identical to the electrical contacts 141. The size of the electrical contacts 141 and 142 may be different. For example, electrical contacts 142 may be smaller than electrical contacts 141.

The electrical contacts 143 may be disposed on bottom surface 112 of the IC 110. The electrical contacts 143 may be electrically connected to the IC 110 through the RDL 119. In some embodiments, the IC 110 may be electrically connected to the substrate 20 through the electrical contacts 143. That is, the electrical contacts (terminals) 143 may be directly contacted to the substrate 20. In some embodiments, the electrical contacts 143 may be substantially identical to the electrical contacts 141. The size of the electrical contacts 141 and 143 may be different. For example, electrical contacts 143 may be smaller than electrical contacts 141.

In some embodiments, the electrical contacts 143 and the electrical contacts 141 and 142 are disposed on opposite sides of the IC 110. Accordingly, the IC 110 can be a double-sided terminal IC configured to provide a vertical electrical path between the substrates 20 and 30. In some embodiments, the IC 110 may be configured to receive a power signal from the substrate 20 via the electrical contacts 143. The IC 110 may be configured to regulate the power signal and transmit the regulated power signal to the substrate 30 via the electrical contacts 141. In some embodiments, the regulated power signal generated by the IC 110 may be processed by the passive element 120 and then transmitted to the substrate 30 via the electrical contacts 142.

In some embodiments, the encapsulant 130 may be disposed on the top surface of 111 of the IC 110. The encapsulant 130 may cover or encapsulate the IC 110. The top surface 111 of the IC 110 may be entirely covered by the encapsulant 130. The encapsulant 130 may cover or encapsulate the passive element 120. In some embodiments, the encapsulant 130 may be disposed between the passive element 120 and the RDL 118. That is, the encapsulant 130 may cover or encapsulate the connectors 150. The passive element 120 may be entirely covered by the encapsulant 130. The encapsulant 130 may encapsulate the electrical contacts 141 and 142. In some embodiments, a portion of the electrical contacts 141 and 142 may be exposed from the encapsulant 130.

In some arrangements, the encapsulant 130 may include an epoxy resin having fillers, a molding compound (e.g., an epoxy molding compound or another molding compound), a polyimide, a phenolic compound or material, a material with a silicone dispersed therein, or a combination thereof.

Referring to FIGS. 1 and 2, the IC 110 may be configured to receive the power signal from the substrate 20 and provide a regulated power signal to the electronic components 41 and 42. In some embodiments, an electrical path P1 from a power source (not shown) passing through the substrate 20 to the electronic component 10 is established. In some embodiments, the electronic component 10 may configured to provide an electrical path P2 between the substrates 20 and 30. In some embodiments, the electrical path P2 from the substrate 20 to the substrate 30 is within a projection of the electronic component 10 (such as, the IC 110) on the substrate 20. For example, a projection of the electrical path P2 between the IC 110 and the substrate 30 on the substrate 20 may be entirely within a projection of the IC 110 on the substrate 20. Referring to FIG. 2, the electrical path P2 may be configured to input a power signal from the bottom surface 112 of the IC 110 facing the substrate 20, through the conductive through vias 115, and output from the top surface 111 of the IC 110 facing the substrate 30. The electrical path P2 may also pass through the passive element 120. In some embodiments, an electrical path P3 passing through the substrate 30 to the electronic components 41 and 42 is established. In some embodiments, the electrical paths P1, P2, and P3 may be power paths. In some embodiments, the electrical path P2 is non-parallel to the electrical paths P1 and P3. For example, the electrical path P2 may be substantially perpendicular to the electrical paths P1 and P3. The IC 110 may be configured to receive the power signal through electrical path P1. The IC 110 may be configured to regulate the power signal and then transmit the regulated power signal to the electronic components 41 and 42 through the electrical path P3. In some embodiments, each of the substrates 20 and 30 may include a power region configured to regulate and transmit the power signal and a signal region for signal communication. The electronic component 10 may be connected to the power region of the substrate 20 and the power region of the substrate 30, so as to provide a direct electrical path therebetween.

In some embodiments, the electrical contacts 143 may be connected between the RDL 119 and the power region of the substrate 20, thereby the IC 110 may be configured to receive the power signal from the power region of the substrate 20 through the electrical contacts 143. In some embodiments, the passive element 120 may be connected between the IC 110 and the power region of the substrate 30. The electrical contacts 142 may connect the passive element 120 and the power region of the substrate 30. In some embodiments, the regulated power signal provided by the IC 110 may be passed through the passive element 120, the electrical contacts 142, and then to the power region of the substrate 30. Therefore, the electronic components 41 and 42 may be configured to receive a regulated power signal provided by the IC 110 through the power region of the substrate 30.

In some embodiments, the interconnector 50 may be configured to support the substrate 30 collaboratively with the electronic component 10 (i.e., the IC 110). In some embodiments, the interconnector 50 may be connected to the signal region of the substrate 20 and the signal region of the substrate 30, so as to provide a signal path between the substrates 20 and 30. For example, the electronic component 43 may be configured to communicate with the electronic component 41 or 42 through the signal region of the substrate 30.

As used herein, a power path may refer to a path dedicated to power supply connections. Additionally, a non-power path may refer to a path through which a non-powered signal (or data) may be transmitted. A non-powered signal may include analog signals, digital signals, clock signals or other electrical signals other than power signals. For example, the electrical path established by the interconnector 50 may be a non-power path.

The IC 110 (for example, PMIC) having double-sided terminals and integrated passive elements, e.g., the passive element 120 may provide a shorter electrical path and thereby reduce power consumption. The vertical electrical connection provided by the electronic component 10 provides a shorter electrical path and decreases the area required on the substrate for power signals. In addition, passive elements (such as inductors, capacitors, or resistors) integrated into the electronic component 10 can even decrease the area of the substrate and increase performance (for example, power stability) of the IC 110.

FIG. 3A is a cross-section of an inductor 120A, in accordance with some embodiments of the present disclosure. FIG. 3B is a top view of the inductor 120A. The inductor 120A may be a magnetic inductor. Referring to FIGS. 3A and 3B, the inductor 120A may include a conductive layer 121 and a magnetic element 122. The conductive layer 121 may be patterned. For example, the conductive layer 121 may form a coil from a top view. In some embodiments, the conductive layer 121 may be embedded in a dielectric layer (not shown).

The magnetic element 122 may be disposed adjacent to the conductive layer 121. The magnetic element 122 may extend through the coil of the conductive layer 121. In some embodiments, the magnetic element 122 may be separated from the conductive layer 121. That is, the magnetic element 122 may not contact the conductive layer 121. In some embodiments, the magnetic element 122 may be positioned in the middle of the conductive layer 121 (or the coil) in the top view.

The (magnetic) inductor 120A may have an inductance value exceeding that of a normal inductor of the same size. The size of the inductor may be the required area (for example, the number of the coils). Therefore, the electronic component 10 in FIGS. 1 and 2 may improve performance with the passive element 120 under the same required area.

FIG. 4A is a cross-section of an inductor 120B, in accordance with some embodiments of the present disclosure. FIG. 4B is a top view of the inductor 120B. The inductor 120B may be a magnetic inductor according to an embodiment different from the inductor 120A. The inductor 120B of FIGS. 4A-4B is similar to the inductor 120A of FIGS. 3A-3B, except that the inductor 120B of FIGS. 4A-4B includes two magnetic elements 123 and 124 in a different arrangement.

Referring to FIGS. 4A and 4B, the inductor 120B includes a conductive layer 121 and two magnetic elements 123 and 124. The conductive layer 112 may be patterned. For example, the conductive layer 121 may form a coil from a top view. In some embodiments, the conductive layer 121 may be embedded in a dielectric layer (not shown).

In some embodiments, the magnetic elements 123 and 124 may be separated from the conductive layer 121. That is, the magnetic elements 123 and 124 may not contact the conductive layer 121. In some embodiments, the magnetic element 123 may be disposed on the conductive layer 121 and extend parallel to the conductive layer 121. The magnetic element 124 may be disposed on the conductive layer 121 opposite to the magnetic element 123. In some embodiments, the magnetic element 124 may extend parallel to the conductive layer 121. In some embodiments, the gaps between the conductive layer 121 and the magnetic elements 123 and 124 may be filled with dielectric material (not shown). The magnetic elements 123 and 124 may overlap the conductive layer 121 in cross-section. Referring to FIG. 4B, the magnetic elements 123 and 124 may overlap the conductive layer 121, wherein the magnetic element 124 is omitted for clarity. In some embodiments, the magnetic elements 123 and 124 may be substantially the same size as the conductive layer 121. For example, the magnetic elements 123 and 124 may be substantially the same width as the conductive layer 121.

Similar to the inductor 120A, the (magnetic) inductor 120B may have an inductance value exceeding that of a normal inductor of the same size.

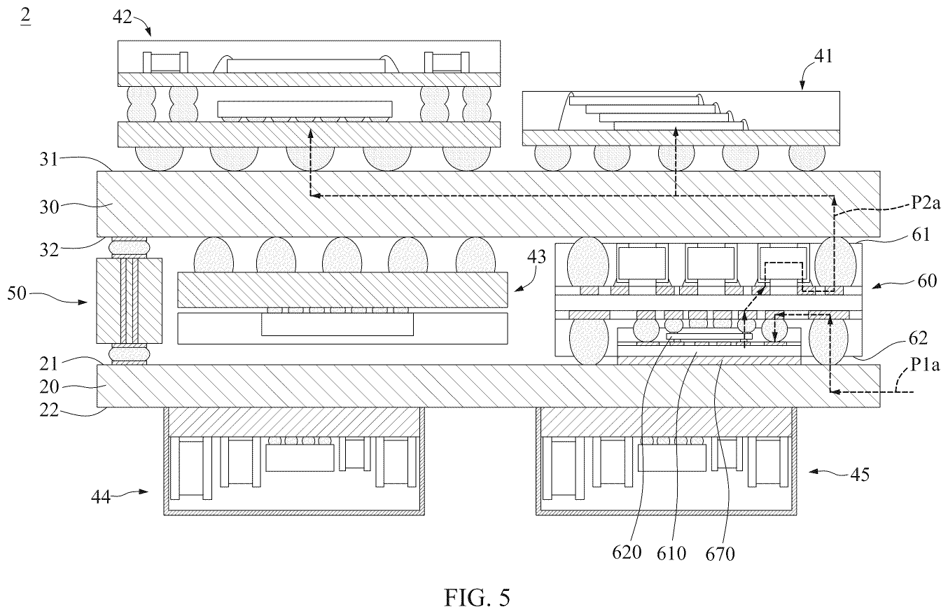

FIG. 5 is a cross-section of an electronic device package 2, in accordance with some embodiments of the present disclosure. The electronic device package 2 of FIG. 5 is similar to the electronic device package 1 of FIG. 1, except for the inclusion of an electronic component 60 for power regulation having an arrangement different from the electronic component 10.

In some embodiments, the electronic component 60 may be disposed between the substrates 20 and 30. The electronic component 60 may be disposed on the top surface 21 of the substrate 20. The electronic component 60 may be disposed on the bottom surface 32 of the substrate 30. In some embodiments, the electronic component 60 may be configured to support the substrate 30. In some embodiments, the electronic component 60 may be configured to provide a vertical electrical path between the substrates 20 and 30.

In some embodiments, the electronic component 60 may include a chip, a die, a circuit, or a circuit element that relies on an external power supply to control or modify electrical signals. For example, the electronic component 60 may include a processor, a controller, a memory, or an input/output (I/O) buffer, etc. In some embodiments, the electronic component 60 may include, for example, a central processing unit (CPU), a microprocessor unit (MPU), a graphics processing unit (GPU), a microcontroller unit (MCU), an application-specific integrated circuit (ASIC), a field-programmable gate array (FPGA), or other type of integrated circuit. For example, the electronic component 60 may include a power management integrated circuit (PMIC).

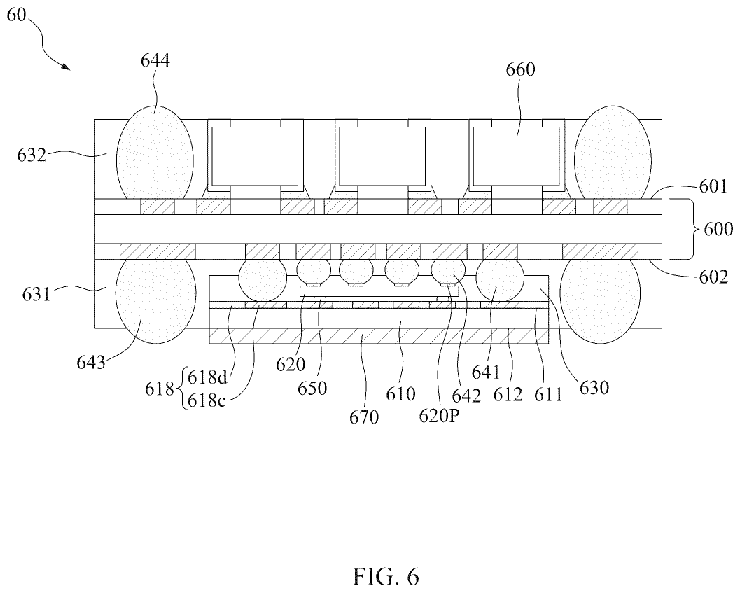

In some embodiments, the electronic component 60 may include a sub-package structure. The electronic component 60 may integrate one or more passive elements. Details of the electronic component 60 are shown in FIG. 6.

FIG. 6 is a cross-section of electronic component 60, in accordance with some embodiments of the present disclosure. Referring to FIG. 6, the electronic component 60 may include a substrate 600, an IC 610, a RDL 618, a passive element 620, encapsulants 630, 631, and 632, electrical contacts 641, 642, 643, and 644, connectors 650, one or more passive elements 660, and a conductive layer 670.

Referring to FIG. 6, the substrate 600 may have a top surface 601 and a bottom surface 602 opposite to the top surface 601. Referring back to FIG. 5, the substrate 600 may be of different width than substrates 20 and 30. For example, the width of the substrate 600 may be less than the width of the substrates 20 and 30.

In some embodiments, the substrate 600 may be multilayered. In some embodiments, the substrate 600 may include at least one dielectric layer and a redistribution structure, traces, and/or circuit, for electrical connection between components, embedded in the dielectric layer. In some embodiments, the substrate 600 may include a circuit board, such as a paper-based copper foil laminate, a composite copper foil laminate, or a polymer-impregnated glass-fiber-based copper foil laminate. In some embodiments, the substrate 600 may include a semiconductor substrate. For example, the substrate 600 may include silicon, germanium or other suitable materials.

The IC 610 may be disposed on the bottom surface 602 of the substrate 600. In some embodiments, the IC 610 may include a top surface 611 and a bottom surface 612 opposite to the top surface 611. In some embodiments, the top surface 611 may be an active surface of the IC 610. That is, the active surface (i.e., the top surface 611) of the IC 610 may face the bottom surface 602 of the substrate 600. The bottom surface 612 may be a backside surface of the IC 610. In some embodiments, the bottom surface 612 of the IC 610 may face the substrate 20 (of FIG. 5). In some embodiments, the IC 610 may be a power regulating component. The IC 610 may include a power management integrated circuit (PMIC). The IC 610 may be configured to provide one or more types of power control to one or more electronic components of the electronic package 2 of FIG. 5.

In some embodiments, the IC 610 may include a voltage regulator, such as a linear regulator (configured to maintain a constant output voltage) or a switching regulator (configured to generate an output voltage higher than or lower than the input voltage). In some embodiments, the IC 610 may include a step-down (buck) converter, a step-up (boost) converter, an analog-to-digital converter, a digital-to-analog converter, an AC-DC converter, a DC-DC converter, other types of converters, or a combination thereof.

The RDL 618 may be disposed on the top surface 611 of the IC 610. In some embodiments, the RDL 618 may include at least one dielectric layer 618d and a conductive trace 618c embedded in the dielectric layer 618d. The RDL 618 may separate the IC 610 from the passive element 620.

In some embodiments, the passive element 620 may be disposed on the IC 610. The passive element 620 may be disposed on the top surface 611 of the IC 610. The passive element 620 may be electrically connected to the IC 610 through the RDL 618. In some embodiments, the passive element 620 may be substantially identical to the passive element 120 of FIG. 2, and thus the details thereof are omitted for clarity. In some embodiments, the passive element 620 may include a magnetic inductor.

In some embodiments, the passive element 620 may be configured to be electrically connected between the IC 610 and the substrate 600. In some embodiments, the passive element 620 may be connected to the IC 610 through the connectors 650. For example, the connectors 650 can include conductive materials, such as solder balls.

The electrical contacts 641 may be disposed on the top surface 611 of the IC 610. The electrical contacts 641 may be electrically connected to the IC 610 through the RDL 618. In some embodiments, the electrical contacts 641 may connect the IC 610 and the substrate 600. The electrical contacts 641 may overlap the passive element 620 horizontally. In some embodiments, the electrical contacts 641 may be configured to transmit a power signal to the IC 610. In some embodiments, the electrical contacts 641 may also be referred to as a terminal, a connecting element, an electrical connector, or the like. In some embodiments, the electrical contacts 641 may include a solder ball, such as a controlled collapse chip connection (C4) bump, a ball grid array (BGA) or a land grid array (LGA).

The electrical contacts 642 may be disposed on the passive element 620. The electrical contacts 642 may be electrical connected to the passive element 620 through conductive pads 620p. The electrical contacts 642 may be disposed between the passive element 620 and the substrate 600. In some embodiments, the electrical contacts 642 may be substantially identical to the electrical contacts 641. The size of the electrical contacts 641 and 642 may be different. For example, the diameter of the electrical contacts 642 may be less than that of the electrical contacts 641.

In some embodiments, the encapsulant 630 may be disposed on the top surface of 611 of the IC 610. The encapsulant 630 may cover or encapsulate the IC 610. The top surface 611 of the IC 610 may be entirely covered by the encapsulant 630. The encapsulant 630 may cover or encapsulate the passive element 620. In some embodiments, the encapsulant 630 may be disposed between the passive element 620 and the RDL 618. That is, the encapsulant 630 may cover or encapsulate the connectors 650. The passive element 620 may be entirely covered by the encapsulant 630. The encapsulant 630 may partially encapsulate the electrical contacts 641 and 642. In some embodiments, a portion of the electrical contacts 641 and 642 may be exposed by the encapsulant 630.

In some arrangements, the encapsulant 630 may include an epoxy resin having fillers, a molding compound (e.g., an epoxy molding compound or another molding compound), a polyimide, a phenolic compound or material, a material with a silicone dispersed therein, or a combination thereof.

The conductive layer 670 may be disposed on the bottom surface 612 (i.e., the backside surface) of the IC 610. In some embodiments, the conductive layer 670 may be thinner than the IC 610. In some embodiments, some conductive elements of the IC 610 may be exposed from the bottom surface 612 and in contact with the conductive layer 670. Referring to FIGS. 5 and 6, the conductive layer 670 may be disposed between and contact the IC 610 and the substrate 20, such that the conductive layer 670 can be configured to dissipate heat of the IC 610 toward the substrate 20. In some embodiments, the conductive layer 670 may include metals or alloys.

The conductive layer 670 may be connected to the IC 610 but without signal exchange. In other words, the conductive layer 670 may not be configured to provide an electrical path. In some embodiments, the conductive layer 670 may be referred to as a heat dissipating element/layer. The conductive layer 670 may be used as a heat sink by taking advantage of its high thermal conductivity.

In some embodiments, the IC 610, passive element 620, and the conductive layer 670 may be manufactured as a sub-package structure first, and then such sub-package structure may be integrated into the electronic component 60.

In some embodiments, the electrical contacts 643 may be disposed on bottom surface 602 of the substrate 600. The electrical contacts 643 may be electrically connected to the IC 610 through the substrate 600 and the electrical contacts 641. In some embodiments, the IC 610 may be electrically connected to the substrate 20 through the electrical contacts 643. The electrical contacts 643 may overlap the IC 610 horizontally. In some embodiments, the electrical contacts 643 may be substantially identical to the electrical contacts 641. The size of the electrical contacts 641 and 643 may be different. For example, the size of the electrical contacts 643 may exceed that of the electrical contacts 641.

In some embodiments, the encapsulant 631 may be disposed on the bottom surface of 602 of the substrate 600. The encapsulant 631 may cover or encapsulate the IC 610. The bottom surface 602 of the substrate 600 may be entirely covered by the encapsulant 631. In some embodiments, the lateral surface of the encapsulant 631 may be substantially aligned with the lateral surface of the substrate 600. The encapsulant 631 may cover or encapsulate the passive element 620. In some embodiments, the encapsulant 631 may be disposed between the substrate 600 and the passive element 620. The encapsulant 631 may cover or encapsulate the electrical contacts 641 and 642. In some embodiments, a portion of the electrical contacts 641 and 642 may be covered or encapsulated by the encapsulant 630, and another portion of the electrical contacts 641 and 642 may be covered or encapsulated by the encapsulant 631.

In some embodiments, the encapsulant 631 may partially cover or encapsulate the electrical contacts 643. A portion of the electrical contacts 643 may be exposed by the encapsulant 631. The conductive layer 670 may be exposed by the encapsulant 631. In some embodiments, the lowermost surface of the conductive layer 670 may be substantially aligned with the lowermost point of the electrical contacts 643. In one embodiment, the lateral surface of the conductive layer 670 may be covered by the encapsulant 631.

In some arrangements, the encapsulant 631 may include an epoxy resin having fillers, a molding compound (e.g., an epoxy molding compound or another molding compound), a polyimide, a phenolic compound or material, a material with a silicone dispersed therein, or a combination thereof.

In some embodiments, one or more passive elements 660 may be disposed on the top surface 601 of the substrate 600. In some embodiments, the passive element 660 and the IC 610 may be disposed on opposite sides of the substrate 600. In other words, the substrate 600 may be interposed between the IC 610 and the passive elements 660. In some embodiments, a projection of the passive element 660 on the substrate 20 may be within a projection of the IC 610 on the substrate 20. That is, the passive element 660 may overlap the IC 610 vertically. In some embodiments, the passive element 660 may overlap the passive element 620 vertically. The passive elements 660 may be electrically connected to the substrate 600. The passive elements 660 may be a capacitor, an inductor, a resistor, or a combination thereof. In some embodiments, the passive elements 660 may be configured to regulate and filter power signals. For example, the passive elements 660 may be configured to receive and process the power signal from the IC 610 and then transmit the regulated power signal to the substrate 30 (of FIG. 5).

The electrical contacts 644 may be disposed on top surface 601 of the substrate 600. In some embodiments, the electrical contacts 644 may overlap the passive elements 660 horizontally. The electrical contacts 644 may be electrically connected to the passive elements 660 through the substrate 600. In some embodiments, the electrical contacts 644 may be electrically connected to the IC 610 through the substrate 600. In some embodiments, the IC 610 may be electrically connected to the substrate 30 through the electrical contacts 644. In some embodiments, the electrical contacts 644 may be substantially identical to the electrical contacts 643. The sizes of electrical contacts 643 and 644 may be different. For example, the diameter of the electrical contacts 644 may be greater than that of the electrical contacts 643.

In some embodiments, the encapsulant 632 may be disposed on the top surface of 601 of the substrate 600. The encapsulant 632 may cover or encapsulate the passive elements 660. The top surface 601 of the substrate 600 may be entirely covered by the encapsulant 632. In some embodiments, the encapsulant 632 may be disposed between the substrate 600 and the passive elements 660. In some embodiments, the lateral surface of the encapsulant 632 may be substantially aligned with the lateral surface of the substrate 600. The encapsulant 632 may cover or encapsulate the electrical contacts 644. In some embodiments, the encapsulant 632 may partially cover or encapsulate the electrical contacts 644. A portion of the electrical contacts 644 may be exposed by the encapsulant 632.

In some arrangements, the encapsulant 632 may include an epoxy resin having fillers, a molding compound (e.g., an epoxy molding compound or another molding compound), a polyimide, a phenolic compound or material, a material with a silicone dispersed therein, or a combination thereof.

Referring to FIGS. 5 and 6, electrical path P1a and P2a provided by the electronic component 60 may be power paths. The IC 610 may be configured to receive the power signal through electrical path Pla. The IC 610 may be configured to regulate the power signal and then transmit the regulated power signal to the electronic components 41 and 42 through the electrical path P2a.

In some embodiments, the electronic component 60 is configured to provide the electrical path P1a from a power source (not shown) passing through the substrate 20 to the bottom surface 62 of the electronic component 60. The electrical path Pla may pass through the electrical contacts 643, the substrate 600, and the electrical contacts 641 to the top surface 611 (i.e., the active surface) of the IC 610. In some embodiments, some of the electrical contacts 641 may be configured to receive the power signals, i.e., input the power signal, while some of the electrical contacts 641 may be configured to transmit the regulated power signal generated by the IC 610, i.e., output the regulated power signal.

In some embodiments, the electronic component 60 may be configured to provide the electrical path P2a from the top surface 61 of the electronic component 60 to the electronic components 41 and 42. The electrical path P2a may start from the top surface 611 of the IC 610 and pass through the passive element 620, the substrate 600, and/or the passive elements 660, and then to the substrate 30, such that the electronic components 41 and 42 could be configured to receive the regulated power signals through the substrate 30. The electrical path P2a may pass through the connectors 650, the passive element 620, the electrical contacts 642, the substrate 600, the passive elements 660, back to another traces of the substrate 600, the electrical contacts 644, and then to the substrate 30. In one embodiment, the electrical path P2a may pass through the electrical contacts 641, the passive elements 660 and to the substrate 30 (i.e., skipping the passive element 620). In another embodiments, the electrical path P2a may pass through the passive element 620, the electrical contacts 642, and to the substrate 30 (i.e., skipping the passive elements 660).

After the regulation of the power signal performed by the IC 610, the regulated power signal may pass through the passive elements for further power regulation. The present practice usually arranges the passive elements for power regulation on the substrate beside the PMIC, which will occupy the area of the substrate. Therefore, the IC 610 (for example, PMIC) integrated with passive elements, e.g., the passive elements 620 and 660, may provide a shorter electrical path and thereby reduce the power consumption. Because the passive elements (such as the passive elements 620 and 660) are integrated in the electronic component 60, the area of the substrate (such as the substrates 20 and 30) for power signals transmission could be decreased. Moreover, the IC 610 could also yield a better performance (for example, the power stability and the power signal processing rate) of the IC 610 once the electrical path between the IC 610 and the passive elements 620 and 660 being short. Also, the sub-package structure of the electronic component 60 may provide a vertical electrical connection between the substrates 20 and 30. Such vertical electrical connection could provide a shorter electrical path. By disposing the conductive layer 670 on the backside of the IC 610, the IC 610 can easily dissipate heat to the substrate 20 via the conductive layer 670.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic device package, comprising:
a first substrate;
a second substrate over the first substrate; and
an integrated circuit (IC) connected between the first substrate and the second substrate, and configured to regulate a power signal, wherein a projection of a power signal path between the IC and the second substrate on the first substrate is entirely within a projection of the IC on the first substrate.

2. The electronic device package of claim 1, further comprising a first terminal and a second terminal on the opposite sides of the IC.

3. The electronic device package of claim 2, wherein the first terminal directly contacts to the first substrate and the second terminal directly contacts to the second substrate.

4. The electronic device package of claim 1, further comprising a first electronic component disposed on the second substrate, wherein the IC is configured to receive the power signal from the first substrate and provide a regulated power signal to the first electronic component.

5. The electronic device package of claim 1, further comprising a third substrate and a passive element, stacked on the third substrate, between the first substrate and the second substrate, wherein the IC and the passive element disposed at opposite sides of the third substrate, respectively.

6. The electronic device package of claim 5, wherein a projection of the passive element on the first substrate is within the projection of the IC.

7. The electronic device package of claim 5, wherein, in a cross-sectional view, the third substrate is entirely between the first substrate and the second substrate.

8. The electronic device package of claim 1, further comprising a heat dissipating layer disposed on a surface of the IC facing the first substrate, wherein the heat dissipating layer contacts the first substrate.

9. The electronic device package of claim 1, wherein the IC is a power management integrated circuit (PMIC).

10. An electronic device package, comprising:
a first substrate;
a first electronic component disposed on the first substrate; and
an integrated circuit (IC) supporting the first substrate and configured to regulate a power signal to the first electronic component.

11. The electronic device package of claim 10, further comprising an inductor connected to the IC and a passive element, wherein the inductor is overlapped with the passive element vertically.

12. The electronic device package of claim 11, further comprising a second substrate interposed between the IC and the passive element, wherein the IC is overlapped with the passive element vertically.

13. The electronic device package of claim 12, further comprising a first electrical connector disposed on a first surface of the second substrate, wherein the first electrical connector overlaps the IC horizontally.

14. The electronic device package of claim 13, further comprising a second electrical connector disposed on a second surface of the second substrate opposite to the first substrate, wherein the second electrical connector overlaps the passive element horizontally.

15. The electronic device package of claim 10, further comprising a passive element configured to filter the regulated power signal and transmit the same to the first substrate.

16. The electronic device package of claim 10, further comprising an interconnector configured to support the first substrate collaboratively with the IC.

17. An electronic device package, comprising:
a first substrate;
a second substrate over the first substrate; and
an integrated circuit (IC) disposed between the first substrate and the second substrate,
wherein a power path consists of a first path through the first substrate, a second path through the IC, and a third path through the second substrate, wherein the second path is non-parallel to the first path and non-parallel to the third path.

18. The electronic device package of claim 17, wherein the IC includes at least one conductive through via connecting two opposite surfaces of the IC.

19. The electronic device package of claim 18, wherein the second path is configured to input a power signal from a first surface of the IC facing the first substrate, through the conductive through via and output from a second surface of the IC facing the second substrate.

20. The electronic device package of claim 17, wherein second path is substantially perpendicular to the first path and to the third path.
